(19) United States
(12) Patent Application Publication
(10) Pub. No.: US 2018/0166529 A1
(43) Pub. Date: Jun. 14, 2018

(54) SEMICONDUCTOR MEMORY DEVICES AND METHODS OF FABRICATING THE SAME

(71) Applicant: Samsung Electronics Co., Ltd., Suwon-si (KR)

(72) Inventors: Hyesung Park, Siheung-si (KR); Suyoung Shin, Hwaseong-si (KR); Jonghyuk Park, Hwaseong-si (KR); Boun Yoon, Seoul (KR); llyoung Yoon, Hwaseong-si (KR); Sangyeol Kang, Yongin-si (KR); SeungHo Park, Suwon-si (KR); Yanghee Lee, Incheon (KR); Wooin Lee, Goyang-si (KR)

(73) Assignee: Samsung Electronics Co., Ltd., Suwon-si (KR)

(21) Appl. No.: 15/831,757

(22) Filed: Dec. 5, 2017

(30) Foreign Application Priority Data
Dec. 14, 2016 (KR) 10-2016-0170558

(51) Int. Cl. H01L 49/02; H01L 27/108

(52) U.S. Cl. CPC H01L 28/84; H01L 27/10808; H01L 27/10885; H01L 27/10852

(57) ABSTRACT

A semiconductor memory devices and methods of fabricating the same are disclosed. For example, the semiconductor memory device including a semiconductor substrate including a cell area and a peripheral area, a plurality of bottom electrodes on the semiconductor substrate at the cell area, a dielectric layer conformally covering top surfaces and sidewalls of the bottom electrodes, and an upper electrode on the dielectric layer and filling between the bottom electrodes may be provided. A surface roughness of a top surface of the upper electrode may be less than a surface roughness of a side surface of the upper electrode.

### CROSS-REFERENCE TO RELATED APPLICATIONS

This U.S. nonprovisional patent application claims priority under 35 U.S.C § 119 to Korean Patent Application No. 10-2016-0170558 filed on Dec. 14, 2016 filed in the Korean Intellectual Property Office (KIPO), the entire contents of which are hereby incorporated by reference.

### BACKGROUND

The present inventive concepts relate to a semiconductor memory devices and/or methods of fabricating the same.

Semiconductor devices are considered to be an important component in the electronic industry because of their small size, multi-function, and/or low fabrication cost. The semiconductor devices are manufactured in a highly integrated manner with the remarkable development of manufacturing technologies. Line widths of patterns of the semiconductor devices have been continuously reduced and have enabled higher integration of the semiconductor devices. To define fine patterns, however, novel exposure techniques and/or expensive exposure techniques are generally desired, and thus making highly integrated semiconductor devices becomes a challenge. Thus, recently various research has been conducted for new integration techniques to define fine patterns. One example approach is to bury word lines inside a semiconductor substrate in DRAM memory devices.

### SUMMARY

Some example embodiments of the present inventive concepts provide semiconductor memory devices having enhanced reliability.

Some example embodiments of the present inventive concepts provide methods of fabricating a semiconductor memory device capable of simplifying processes.

According to an example embodiment of the present inventive concepts, a semiconductor memory device includes a semiconductor substrate including a cell area and a peripheral area, a plurality of bottom electrodes on the semiconductor substrate at the cell area, a dielectric layer conformally covering top surfaces and sidewalls of the bottom electrodes, and an upper electrode on the dielectric layer and filling a space between the bottom electrodes, a surface roughness of a top surface of the upper electrode being less than a surface roughness of a side surface of the upper electrode.

According to an example embodiment of the present inventive concepts, a semiconductor memory device includes a semiconductor substrate including a cell area and a peripheral area, a plurality of bottom electrodes on the semiconductor substrate at the cell area, a dielectric layer conformally covering top surfaces and sidewalls of the bottom electrodes, an upper electrode on the dielectric layer and filling a space between the bottom electrodes, the upper electrode including a silicon germanium layer, and a first interlayer dielectric layer exposing a top surface of the upper electrode and covering the peripheral area, a top surface of the first interlayer dielectric layer being coplanar with the top surface of the upper electrode.

According to an example embodiment of the present inventive concepts, a method of fabricating a semiconductor memory device includes providing a semiconductor substrate including a cell area and a peripheral area, forming a plurality of bottom electrodes on the semiconductor substrate at the cell area, forming a dielectric layer conformally covering top surfaces and sidewalls of the bottom electrodes, forming a silicon germanium layer used as an upper electrode on the dielectric layer, forming a first interlayer dielectric layer covering the cell area and the peripheral area, and after forming the first interlayer dielectric layer, performing a chemical mechanical polishing process with respect to the first interlayer dielectric layer to expose a top surface of the silicon germanium layer at the cell area and leave the first interlayer dielectric layer at the peripheral area.

### BRIEF DESCRIPTION OF THE DRAWINGS

FIG. 1 is a plan view illustrating a semiconductor memory device according to an example embodiment of the present inventive concepts.

FIG. 2 is a cross-sectional view illustrating a semiconductor memory device according to an example embodiment of the present inventive concepts.

FIGS. 3 to 8 are cross-sectional views illustrating a method of fabricating the semiconductor memory device of FIG. 2.

### DETAILED DESCRIPTION

It will be hereinafter described in detail example embodiments of the present inventive concepts in conjunction with the accompanying drawings.

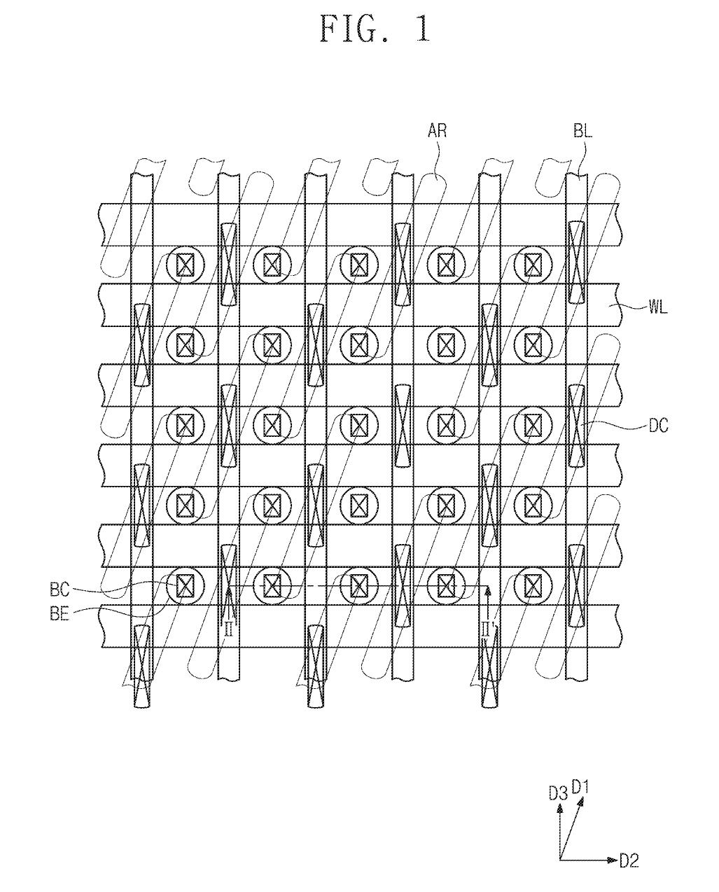

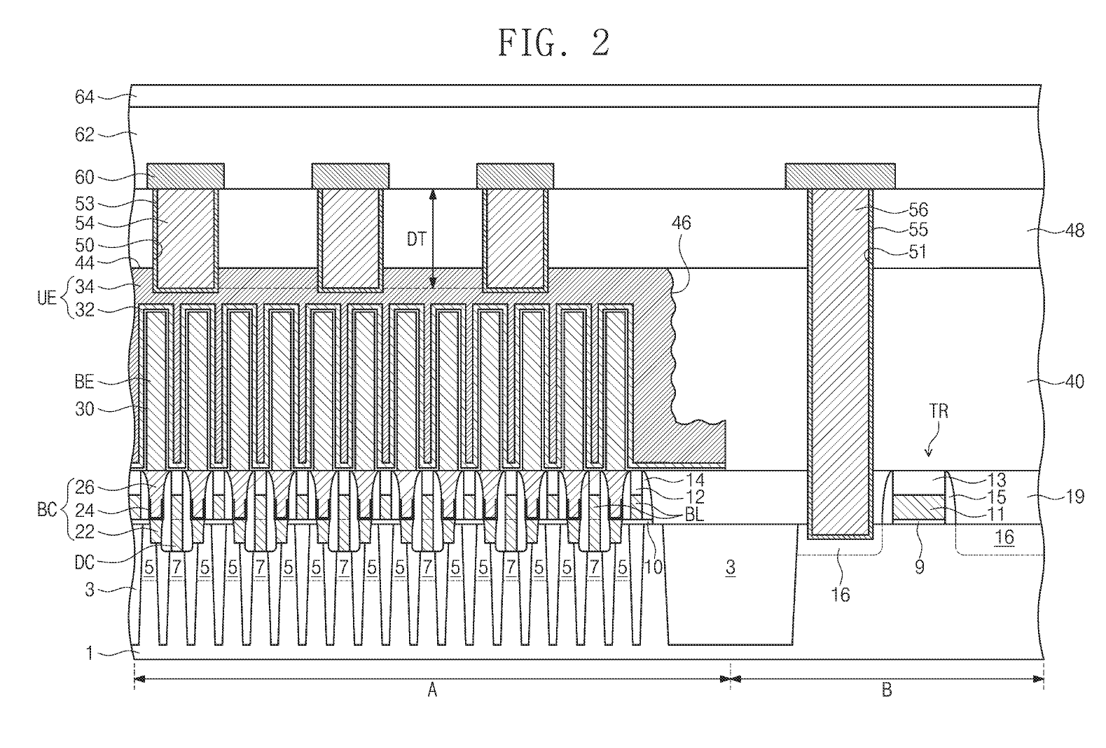

FIG. 1 is a plan view illustrating a semiconductor memory device according to an example embodiment of the present inventive concepts. FIG. 2 is a cross-sectional view illustrating a semiconductor memory device according to an example embodiment of the present inventive concepts.

Referring to FIGS. 1 and 2, a semiconductor substrate 1 may include a cell area A and a peripheral area B. The cell area A may be a cell array region or memory cell blocks. The peripheral area B may be a peripheral circuit region or a core region. A DRAM may be adopted as a semiconductor memory device according to an example embodiment of the present inventive concepts. The cell area A illustrated in FIG. 2 is a cross-sectional view shown in the cell area A may correspond to a cross-sectional view taken along line II-II′ in a plan view of FIG. 1. The semiconductor substrate 1 may be provided therein with device isolation layers 3 to define active regions AR. Further, the device isolation layers 3 may divide the cell area A and the peripheral area B from each other. The active regions AR at the cell area A may have a plurality of bar shapes extending in a first direction D1. Although not shown in FIG. 2, the active regions AR may be traversed by a plurality of word lines WL that extend in a second direction D2 crossing the first direction D1. The word lines WL may be buried within the semiconductor substrate 1. Cell gate dielectric layers (not shown) may be interposed between the semiconductor substrate 1 and the word lines WL, and word line capping patterns (not shown) may be disposed on upper portions of the word lines WL. The word line capping patterns (not shown) may have their top surfaces coplanar with a top surface of the semiconductor substrate 1. A first impurity region 5 may be disposed in the semiconductor substrate 1 on a side of each of the word lines WL, and a second impurity region 7 may be disposed in the semiconductor substrate 1 on the other side of each of the word lines WL. The first impurity region 5 may correspond to, for example, a source region of a memory cell transistor. The second impurity region 7 may correspond to, for example, a drain region of a memory cell transistor.

At the cell area A, the semiconductor substrate 1 may be covered with a first interlayer dielectric layer 10. The first interlayer dielectric layer 10 may be composed of an insulation layer (e.g., a silicon oxide layer, a silicon nitride layer, or a silicon oxynitride layer). The first interlayer dielectric layer 10 may be provided thereon with a plurality of bit lines BL extending in parallel in a third direction D3 crossing both the first and second directions D1 and D2. The bit lines BL may be electrically connected to the second impurity regions 7 through bit line contact plugs DC. The bit lines BL may have their top surfaces covered with bit line capping patterns 12. A bit line spacer 14 may be provided to cover sidewalls of the bit line capping pattern 12, the bit line BL, and the bit line contact plug DC. Neighboring bit lines BL may be provided therebetween with a bottom electrode contact plug BC contacting the first impurity region 5. The bottom electrode contact plug BC may include, for example, an impurity-doped polysilicon pattern 22, a first barrier metal layer 24, and a metal pattern 26. The first barrier metal layer 24 may include, for example, a titanium/titanium nitride layer. The metal pattern 26 may include, for example, tungsten. The bottom electrode contact plugs BC may have their top surfaces coplanar with top surfaces of the bit line capping patterns 12 covering the top surfaces of the bit lines BL. The bit lines BL and the bit line contact plugs DC may be electrically insulated from the bottom electrode contact plugs BC by the bit line spacers 14.

A peripheral transistor TR may be disposed at the peripheral area B. The peripheral transistor TR may include a peripheral gate dielectric layer 9, a peripheral gate electrode 11, a peripheral capping pattern 13, and a peripheral spacer 15 covering sidewalls of the peripheral gate electrode 11 and the peripheral capping pattern 13. The peripheral transistor TR may further include a peripheral source/drain region 16 disposed in the semiconductor substrate 1 on opposite sides of the peripheral gate dielectric layer 9. The peripheral area B may be covered with a second interlayer dielectric layer 19. The second interlayer dielectric layer 19 may cover a side surface of the bit line spacer 14 positioned on an edge of the cell area A. The second interlayer dielectric layer 19 may have a top surface coplanar with top surfaces of the bit line capping pattern 12 and the peripheral capping pattern 13.

At the cell area A, a bottom electrode BE may be disposed on each of the bottom electrode contact plugs BC. The bottom electrode BE may be formed of a conductive material, for example, impurity-doped polysilicon or formed of a metal-containing layer (e.g., a titanium nitride layer). The bottom electrodes BE may have a plug or cylindrical shape. A dielectric layer 30 may be provided to conformally cover top and side surfaces of the bottom electrodes BE and the top surfaces of the bit line capping patterns 12. The dielectric layer 30 may be formed of a material whose dielectric constant is greater than that of a silicon oxide layer. For example, the dielectric layer 30 may be oxide, nitride, silicide, oxynitride, or silicide oxynitride including at least one of hafnium (Hf), aluminum (Al), zirconium (Zr), and lanthanum (La). The dielectric layer 30 may be conformally covered with a metal-containing layer 32. The metal-containing layer 32 may be provided thereon with a silicon germanium layer 34 to fill spaces between the bottom electrodes BE. The metal-containing layer 32 may be, for example, a titanium nitride layer. The silicon germanium layer 34 may be doped with an impurity so as to have conductivity. The metal-containing layer 32 and the silicon germanium layer 34 may constitute an upper electrode UE. The bottom electrode BE, the dielectric layer 30, and the upper electrode UE may constitute a capacitor.

The silicon germanium layer 34 may include a top surface 44 and a side surface 46. The top surface 44 of the silicon germanium layer 34 may be positioned to overlap the bottom electrodes BE, and the side surface 46 of the silicon germanium layer 34 may adjoin the side surface of the bottom electrode BE disposed on an edge of the cell area A. The top surface 44 of the silicon germanium layer 34 may have a surface roughness less than that of the side surface 46 of the silicon germanium layer 34. For example, the top surface 44 of the silicon germanium layer 34 may be flat to exhibit a surface roughness of about 10 nm RMS (Root Mean Square) or less. The side surface 46 of the silicon germanium layer 34 may exhibit a surface roughness between about 10 nm RMS and about 1000 nm RMS. The side surface 46 of the silicon germanium layer 34 may have a higher surface roughness that the top surface 44 thereof due to its natural grain size.

The peripheral area B may be provided thereon with a third interlayer dielectric layer 40 to cover the peripheral transistor TR. The third interlayer dielectric layer 40 may also cover the side surface 46 of the silicon germanium layer 34. The third interlayer dielectric layer 40 may be formed of a layer of PE (Plasma Enhanced)-TEOS (Tetra Ethyl Ortho Silicate), BPSG (Boron Phosphorus Silicate Glass), PSG (Phosphorus Silicate Glass), or HDP (High Density Plasma) oxide. The third interlayer dielectric layer 40 may have a flat top surface. The top surface 44 of the silicon germanium layer 34 may be coplanar with the top surface of the third interlayer dielectric layer 40.

A fourth interlayer dielectric layer 48 may be provided to cover the silicon germanium layer 34 and the third interlayer dielectric layer 40. The fourth interlayer dielectric layer 48 may be formed of a material identical or similar to that of the third interlayer dielectric layer 40. The cell area A may be provided thereon with upper electrode contact plugs 54 to penetrate the fourth interlayer dielectric layer 48 so as to be electrically connected to the silicon germanium layer 34. The upper electrode contact plugs 54 may be disposed in upper electrode contact holes 50. The upper electrode contact plugs 54 may be formed of metal (e.g., tungsten). Each of the upper electrode contact plugs 54 may have a width greater than that of each of the bottom electrodes BE. Thus, the upper electrode contact plug 54 may have a reduced electrical resistance, and the upper electrode UE may be easily supplied with voltage.

Each of the upper electrode contact plugs 54 may be disposed to overlap at least two bottom electrodes BE at the same time. A second barrier metal layer 53 may be provided to cover sidewalls and bottom surfaces of the upper electrode contact plugs 54. The second barrier metal layer 53 may be formed of, for example, a titanium/titanium nitride layer.

The upper electrode contact plugs 54 may have depths DT each of which corresponds to a length measured from a top surface of the fourth interlayer dielectric layer 48 and a bottom surface of a corresponding one of the upper electrode contact plugs 54, and a deviation of depths DT may be about 10 nm or less. As such, the depths DT of the upper electrode contact plugs 54 (or depths of the upper electrode contact holes 50) may be same or substantially similar to each other. The flat top surface 44 of the silicon germanium layer 34 may cause the upper electrode contact plugs 54 to have a same or substantially similar depth DT to each other. Thus, an electrical short between memory cells occurring when the bottom electrodes BE make contact with the upper electrode contact plug 54, which penetrates the dielectric layer 30, may be prevented. The upper electrode contact holes 50 may have their floor surfaces, which are disposed in the silicon germanium layer 34 and spaced apart from the metal-containing layer 32.

The upper electrode UE may be electrically connected to the upper electrode contact plug 54 that penetrates a single layer (e.g., the fourth interlayer dielectric layer 48). As a result, the upper electrode contact plug 54 may have a reduced burden in terms of a penetrating thickness in comparison with a case where the upper electrode contact plug 54 penetrates two interlayer dielectric layers. Thus, a problem that the upper electrode contact hole 50 is not properly opened may be prevented or mitigated. A semiconductor memory device having enhanced reliability may be fabricated.

The peripheral area B may be provided thereon with a peripheral source/drain region 16 electrically connected to a peripheral contact plug 56 that penetrates the fourth interlayer dielectric layer 48 and the third interlayer dielectric layer 40. The peripheral contact plug 56 may be disposed in a peripheral contact hole 51. A third barrier metal layer 55 may be provided to cover a sidewall and a bottom surface of the peripheral contact plug 56. The third barrier metal layer 55 may include, for example, a titanium/titanium nitride layer. The fourth interlayer dielectric layer 48 may be provided thereon with routing lines 60 electrically connected to the upper electrode contact plugs 54 and the peripheral contact plug 56. The fourth interlayer dielectric layer 48 may be sequentially covered with a fifth interlayer dielectric layer 62 and a passivation layer 64.

In some example embodiments of the present inventive concepts, the upper electrode UE may include the metal-containing layer 32. In some other example embodiments, the upper electrode UE may include only the silicon germanium layer 34 without the metal-containing layer 32.

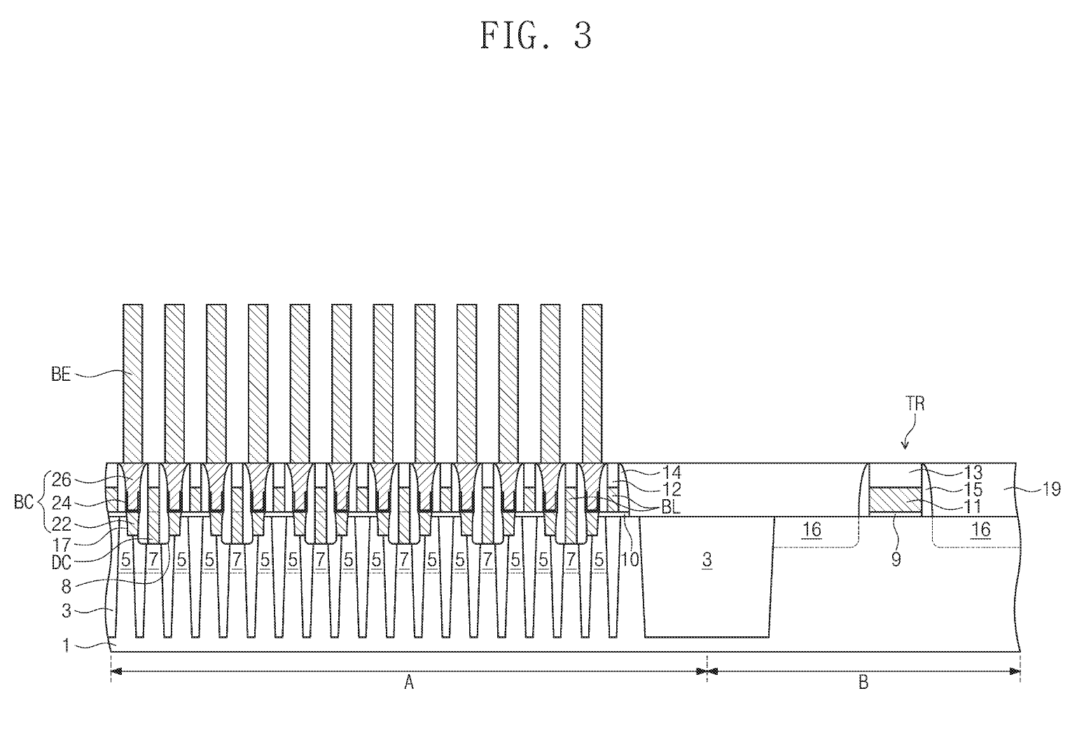

FIGS. 3 to 8 are cross-sectional views illustrating a method of fabricating the semiconductor memory device of FIG. 2.

Referring to FIGS. 1 and 3, a device isolation layer 3 may be formed in a semiconductor substrate 1 including a cell area A and a peripheral area B, such that the cell area A and the peripheral area B may be divided from each other and active regions AR may be defined on each of the areas A and B. An STI (Shallow Trench Isolation) method may be employed to form the device isolation layer 3. The device isolation layer 3 may include one or more of a silicon oxide layer, a silicon nitride layer, and a silicon oxynitride layer. At the cell area A, the active regions AR may be formed to have a plurality of bar shapes extending in a first direction D1. As not shown in FIG. 3, the device isolation layer 3 and the semiconductor substrate 1 may be etched to form a plurality of grooves (not shown) extending in parallel in a second direction D2 crossing the first direction D1 and then word line cell gate dielectric layers (not shown), word lines WL, and word line capping patterns (not shown) may be formed in the grooves. An ion implantation process may be performed to form a first impurity region 5 and a second impurity region 7 on opposite sides of each of the word lines WL.

Subsequently, at the cell area A, a first interlayer dielectric layer 10 may be formed to cover the semiconductor substrate 1. The first interlayer dielectric layer 10 may be patterned to form a bit line contact hole 8 through which the second impurity region 7 is exposed. The bit line contact hole 8 may be filled with a conductive layer, which is formed on the semiconductor substrate 1 on which the bit line contact hole 8 is formed. A bit line capping pattern may be formed on the conductive layer and then used as an etch mask to etch the conductive layer, thereby forming bit lines BL and bit line contact plugs DC. An insulation layer may be conformally deposited and then anisotropically etched to form bit line spacers 14 each of which covers sidewalls of the bit line BL and the bit line contact plug DC.

At the peripheral area B, a gate dielectric layer, a conductive layer, and a capping layer may be stacked and then patterned to form a peripheral gate dielectric layer 9, a peripheral gate electrode 11, and a peripheral capping pattern 13. Thereafter, peripheral spacers 15 may be formed to cover sidewalls of the peripheral gate dielectric layer 9, the peripheral gate electrode 11, and the peripheral capping pattern 13. The peripheral gate dielectric layer 9 may be formed when the first interlayer dielectric layer 10 is formed. The peripheral gate electrode 11 and the peripheral capping pattern 13 may be formed simultaneously with the formation of the bit lines BL and the bit line capping patterns 12, respectively. The peripheral spacers 15 may be formed simultaneously with the formation of the bit line spacers 14. An ion implantation process may be performed to form a peripheral source/drain region 16 at the peripheral area B. A second interlayer dielectric layer 19 may be formed on an entire surface of the semiconductor substrate 1, and then a chemical mechanical polishing process may be performed to expose top surfaces of the capping patterns 12 and 13.

At the cell area A, a bottom electrode contact hole 17 may be formed by removing the second interlayer dielectric layer 19 between the bit lines BL, the first interlayer dielectric layer 10 below the second interlayer dielectric layer 19, and a portion of the semiconductor substrate 1 below the first interlayer dielectric layer 10. The bottom electrode contact hole 17 may be provided therein with a bottom electrode contact plug BC including a polysilicon pattern 22, a first barrier metal layer 24, and a metal pattern 26.

A mold layer (not shown) may be formed on the entire surface of the semiconductor substrate 1, and a bottom electrode hole may be formed in the mold layer. The bottom electrode hole may be filled with a conductive layer, and then an etching process may be performed to form bottom electrodes BE. After that, the mold layer may be removed to expose a top surface of the second interlayer dielectric layer 19 and top and side surfaces of the bottom electrodes BE.

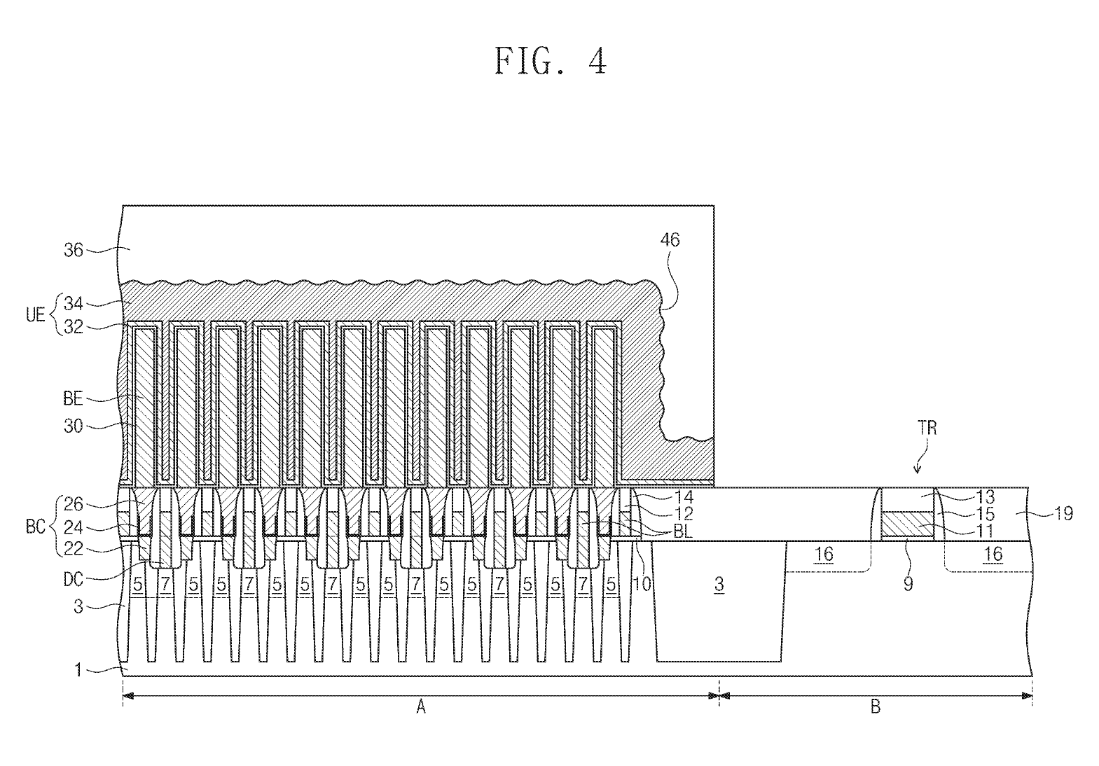

Referring to FIG. 4, a dielectric layer 30 may be conformally formed on the entire surface of the semiconductor substrate 1. The dielectric layer 30 may be formed by atomic layer deposition or chemical vapor deposition. A metal-containing layer 32 may be conformally formed on the dielectric layer 30. The metal-containing layer 32 may be formed by MOCVD (Metal Organic Chemical Vapor Deposition). A silicon germanium layer 34 may be formed on the metal-containing layer 32. The silicon germanium layer 34 may be formed by chemical vapor deposition. An ion implantation process may be performed to dope the silicon germanium layer 34 with an impurity. In some example embodiments, an impurity may be in-situ doped into the silicon germanium layer 34 during its deposition.

An annealing process may be performed to crystallize the silicon germanium layer 34. In this step, due to its grain size, the silicon germanium layer 34 may have an uneven surface (e.g., having a surface roughness between about 10 nm and about 1000 nm). In case that a top surface of the silicon germanium layer 34 has the above-mentioned surface profile, a likelihood of occurrence of process error may increase due to difficulty in controlling a depth of an upper electrode contact hole that is formed in a subsequent process. The annealing process may be performed at a relatively low temperature of less than about 550° C. If a polysilicon layer is used in the place of the silicon germanium layer 34, the annealing process may be performed at a relatively high temperature of more than about 600° C. The relatively high annealing temperature may cause the dielectric layer 30 to deteriorate such that a leakage current may increase when a semiconductor memory device is operated later on. According to some example embodiments of the present inventive concepts, however, as the silicon germanium layer 34 is used as an upper electrode layer, the annealing process may be performed at a relatively low temperature. Thus, the dielectric layer 30 may be prevented from deteriorating.

It may be difficult to form the metal-containing layer 32 having a relatively high thickness. Accordingly, when the upper electrode UE is composed of only the metal-containing layer 32, the bottom electrodes BE may be exposed when an upper electrode contact hole 50 is formed in a subsequent process. The silicon germanium layer 34 according to an example embodiment may serve not only as the upper electrode but also as a buffer layer when an upper electrode contact hole 50 is formed in a subsequent process.

A first mask pattern 36 may be formed to selectively cover the silicon germanium layer 34 at the cell area A. The first mask pattern 36 may be formed of a material having an etch selectivity to the silicon germanium layer 34. For example, the first mask pattern 36 may be formed of a silicon nitride layer. The first mask pattern 36 may be used as an etch mask to remove the silicon germanium layer 34, the metal-containing layer 32, and the dielectric layer 30 from the peripheral area B, and thus the top surface of the second interlayer dielectric layer 19 may be exposed and an upper electrode UE may be formed.

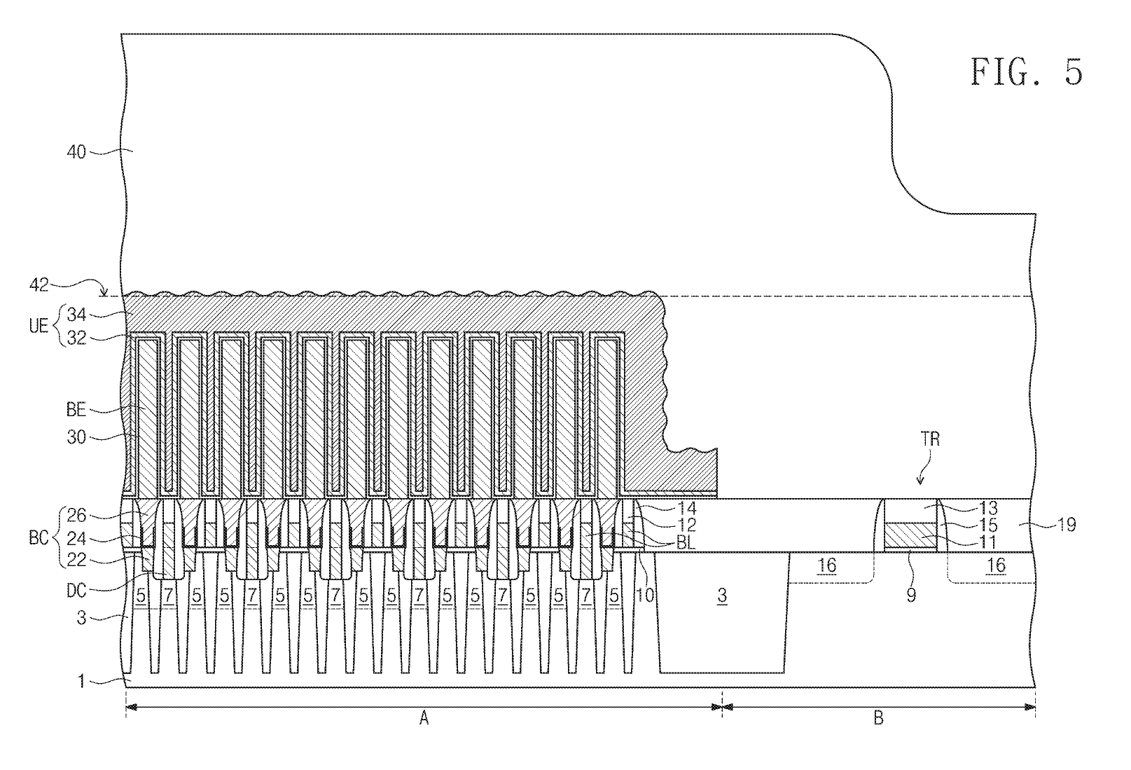

Referring to FIG. 5, the first mask pattern 36 may be selectively removed. When the first mask pattern 36 is formed of a silicon nitride layer, an etchant such as phosphoric acid may be used to remove the first mask pattern 36. The removal of the first mask pattern 36 may reveal the uneven surface of the silicon germanium layer 34. A third interlayer dielectric layer 40 may be deposited on the entire surface of the semiconductor substrate 1. The third interlayer dielectric layer 40 may be formed to have a thickness greater than a height from the top surface of the second interlayer dielectric layer 19 to a top surface of the upper electrode UE.

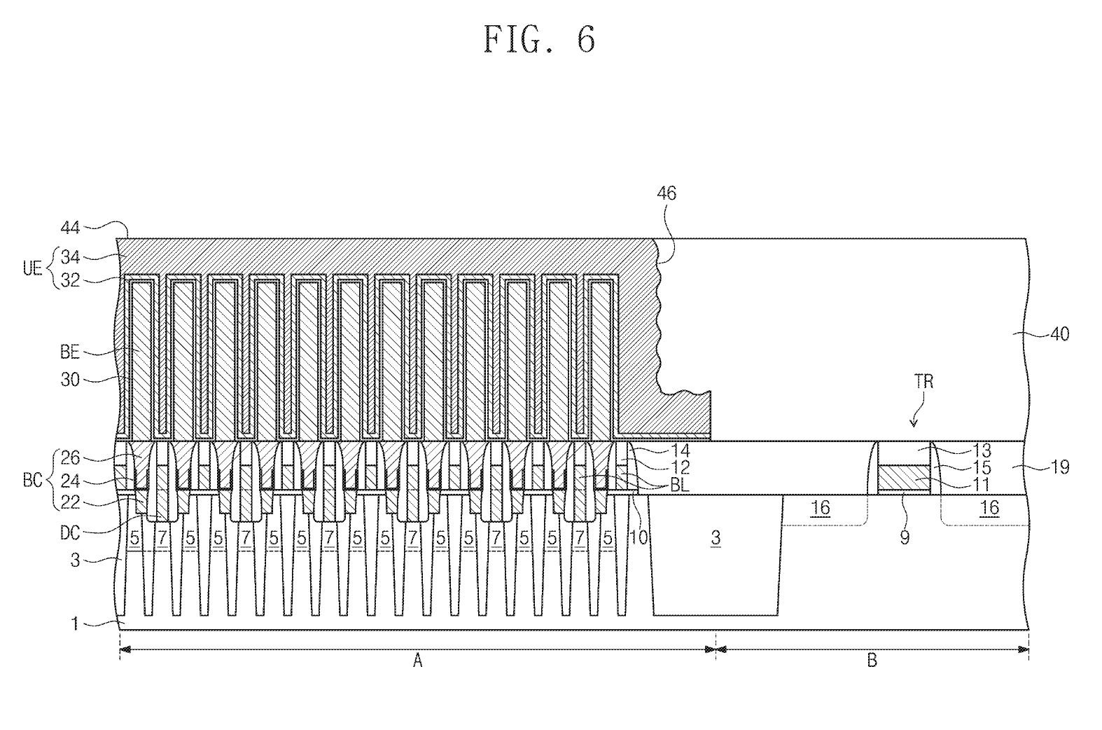

Referring to FIGS. 5 and 6, a chemical mechanical polishing process may be performed to remove the third interlayer dielectric layer 40 on the top surface of the upper electrode UE such that the top surface of the upper electrode UE may be exposed and the third interlayer dielectric layer 40 may remain at the peripheral area B. The chemical mechanical polishing process may be performed until reaching a dotted line 42 of FIG. 5. That is, the chemical mechanical polishing process may partially remove an upper portion of the silicon germanium layer 34. As such, a top surface 44 of the silicon germanium layer 34 may become flat with exhibiting a surface roughness of about 10 nm RMS or less. Therefore, when an upper electrode contact holes are formed later, the upper electrode contact holes may be to have a same depth or substantially similar depths to each other. Thus, a problem that the upper electrode contact holes 50 are not properly opened may be and prevented or mitigated.

In case that a metal-containing layer is used as a CMP (Chemical Mechanical Polishing) stop layer when a chemical mechanical polishing process is performed (or, in case a metal-containing layer is exposed), chemical mechanical polishing equipment may suffer from metal contamination and thus the chemical mechanical polishing process should stop before reaching the upper electrode (e.g., the metal-containing layer). However, according to some example embodiments of the present inventive concepts, because a silicon germanium layer is used as a CMP stop layer, the chemical mechanical polishing process may be conducted until reaching the upper electrode (e.g., the silicon germanium layer) without equipment contamination.

Further, in case that an upper electrode is only composed of a metal-containing layer, a partial CMP process may be desired to leave a portion of the third interlayer dielectric layer 40 on the upper electrode UE so as to prevent the metal-containing layer from being exposed. In this case, the third interlayer dielectric layer 40 may be caused to have a relative wide thickness variation depending on its locations on central and edge portions of a wafer. However, according to some example embodiments of the present inventive concepts, because the silicon germanium layer 34 is used as a CMP stop layer, the third interlayer dielectric layer 40 may be prevented from the aforementioned wide thickness variation depending on its locations.

Furthermore, because the silicon germanium layer 34 is used as a CMP stop layer, the third interlayer dielectric layer 40 may be removed from the cell area A without using an additional mask pattern. Thus, a simplified process, which does not perform deposition, photolithography, and etching processes associated with the additional mask pattern, may be achieved.

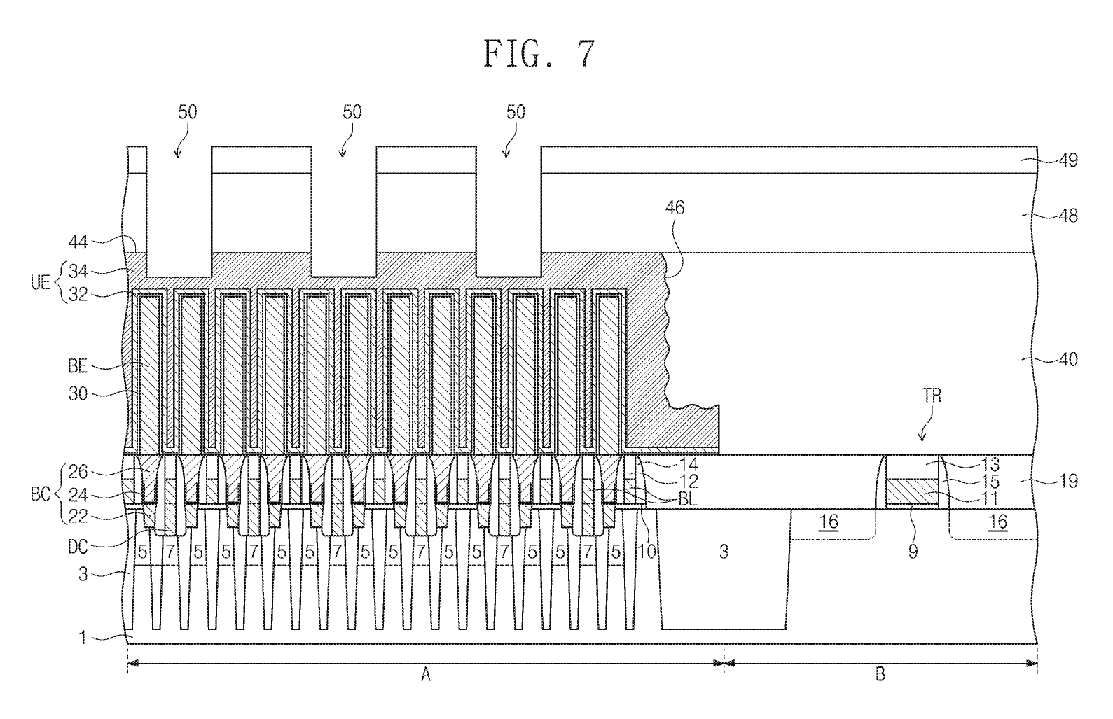

Referring to FIG. 7, a fourth interlayer dielectric layer 48 may be formed on the entire surface of the semiconductor substrate 1. The fourth interlayer dielectric layer 48 may be provided thereon with a second mask pattern 49 to limit a position of an upper electrode contact hole. The fourth interlayer dielectric layer 48 may be patterned using the second mask pattern 49 as an etch mask to form upper electrode contact holes 50 through which the silicon germanium layer 34 is exposed. The upper electrode contact holes 50 may have a width greater than that of the bottom electrode BE. Each of the upper electrode contact holes 50 may be formed to vertically overlap at least two bottom electrodes BE. The upper electrode contact hole 50 may be formed to have a bottom surface that is disposed in the silicon germanium layer 34 and spaced apart from the metal-containing layer 32. As the silicon germanium layer 34 has the flat top surface 44, the upper electrode contact holes 50 may be formed to have a same depth or substantially similar depths to each other.

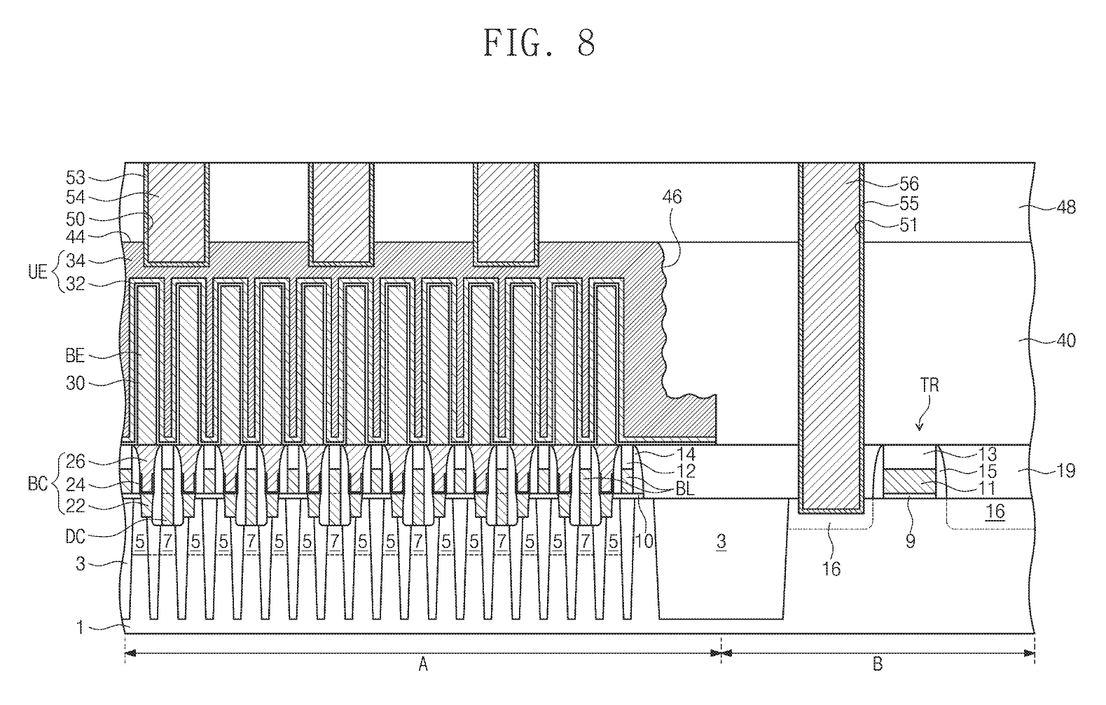

Referring to FIG. 8, at the peripheral area B, the fourth interlayer dielectric layer 48, the third interlayer dielectric layer 40, and the second interlayer dielectric layer 19 may be patterned to form a peripheral contact hole 51 through which the peripheral source/drain region 16 is exposed. A second barrier metal layer 53 and a third barrier metal layer 55 may be formed to conformally cover sidewalls of the upper electrode contact hole 50 and the peripheral contact hole 51, respectively. Thereafter, a conductive layer may be deposited and then a planarization etching process may be performed to form an upper electrode contact plug 54 and a peripheral contact plug 56 in the upper electrode contact hole 50 and the peripheral contact hole 51, respectively.

Referring back to FIG. 2, the upper electrode contact plugs 54 and the peripheral contact plug 56 may be provided thereon with routing lines 60 connected thereto. A fifth interlayer dielectric layer 62 and a passivation layer 64 may be sequentially formed on the fourth interlayer dielectric layer 48. Through aforementioned processes, a semiconductor memory device may be fabricated as shown in FIG. 2.

In a semiconductor memory device according to some example embodiments of the present inventive concepts, because an upper electrode includes a silicon germanium layer whose top surface is flat with exhibiting a surface roughness of less than about 10 nm RMS (Root Mean Square), upper electrode contact holes may have a substantially uniform depth. Thus, an electrical short between memory cells occurring when bottom electrodes make contact with an upper electrode contact plug, which penetrates a dielectric layer, may be prevented. Further, because the upper electrode is electrically connected to the upper electrode contact plug that penetrates a single interlayer dielectric layer, the upper electrode contact plug may have a reduced burden in terms of a penetrating thickness in comparison with a case where the upper electrode contact plug penetrates two interlayer dielectric layers. Thus, a problem that an upper electrode contact hole is not properly opened may be prevented or mitigated. A semiconductor memory device having enhanced reliability may be fabricated. Further, because the upper electrode contact plug has a width greater than those of bottom electrodes, the upper electrode contact plug may have a reduced electrical resistance and the upper electrode may be easily supplied with voltage from outside.

In a method of fabricating a semiconductor memory device, a silicon germanium layer may be used as the upper electrode. As such, when a chemical mechanical polishing (CMP) process is performed on an interlayer dielectric layer, the silicon germanium layer may be used as a CMP stop layer without contaminating CMP equipment. Therefore, because there is no need to leave a portion of the interlayer dielectric layer on the upper electrode layer, the interlayer dielectric layer may be prevented from having varied thicknesses depending on its location on central and edge portions of a wafer. Furthermore, the interlayer dielectric layer may be removed from a cell area without using an additional mask pattern. Thus, a simplified process, which does not perform deposition, photolithography, and etching processes associated with the additional mask pattern, may be achieved. Moreover, because the silicon germanium layer has a relatively flat top surface, the upper electrode contact hole may be easily controlled in its depth and prevented from being not opened.

1. A semiconductor memory device, comprising:
a semiconductor substrate including a cell area and a peripheral area;
a plurality of bottom electrodes on the semiconductor substrate at the cell area;
a dielectric layer conformally covering top surfaces and sidewalls of the bottom electrodes; and
an upper electrode on the dielectric layer and filling a space between the bottom electrodes, a surface roughness of a top surface of the upper electrode being less than a surface roughness of a side surface of the upper electrode.

2. The device of claim 1, wherein the upper electrode comprises a silicon germanium layer.

3. The device of claim 2, wherein
the surface roughness of the top surface of the upper electrode is about 10 nm Root Mean Square (RMS) or less, and
the surface roughness of the side surface of the upper electrode is between about 10 nm RMS and about 1000 nm.

4. The device of claim 1, further comprising:
a first interlayer dielectric layer exposing the upper electrode and covering the peripheral ara,
wherein the top surface of the upper electrode is coplanar with a top surface of the first interlayer dielectric layer.

5. The device of claim 4, further comprising:
a second interlayer dielectric layer covering both the upper electrode and the first interlayer dielectric layer; and
a plurality of upper electrode contact plugs penetrating the second interlayer dielectric layer and being in contact with the upper electrode,
wherein the upper electrode contact plugs have depths each of which is measured from a top surface of the second interlayer dielectric layer to a bottom surface of a corresponding one of the upper electrode contact plugs, and a deviation of the depths ranges from about 0 nm to about 10 nm.

6. The device of claim 5, wherein each of the upper electrode contact plugs has a width greater than that of each of the bottom electrodes and vertically overlaps at least two bottom electrodes.

7. The device of claim 2, wherein the upper electrode further comprises a metal-containing layer interposed between the silicon germanium layer and the dielectric layer.

8. A semiconductor memory device, comprising:
a semiconductor substrate including a cell area and a peripheral area;
a plurality of bottom electrodes on the semiconductor substrate at the cell area;
a dielectric layer conformally covering top surfaces and sidewalls of the bottom electrodes;
an upper electrode on the dielectric layer and filling a space between the bottom electrodes, the upper electrode including a silicon germanium layer, and
a first interlayer dielectric layer exposing a top surface of the upper electrode and covering the peripheral area, a top surface of the first interlayer dielectric layer being coplanar with the top surface of the upper electrode.

9. The device of claim 8, wherein
a top surface of the silicon germanium layer has a surface roughness ranging from about 0 nm Root Mean Square (RMS) to about 10 nm, and
a side surface of the silicon germanium layer has a surface roughness between about 10 nm RMS and about 1000 nm RMS.

10. The device of claim 8, further comprising:
a second interlayer dielectric layer covering both the upper electrode and the first interlayer dielectric layer; and
a plurality of upper electrode contact plugs penetrating the second interlayer dielectric layer and contacting the upper electrode,
wherein the upper electrode contact plugs have depths each of which is measured from a top surface of the second interlayer dielectric layer to a bottom surface of a corresponding one of the upper electrode contact plugs, the depths being substantially the same.

11. The device of claim 10, wherein each of the upper electrode contact plugs has a width greater than that of each of the bottom electrodes and vertically overlaps at least two bottom electrodes.

12.-18. (canceled)

19. A semiconductor memory device, comprising:
a semiconductor substrate including a cell area and a peripheral area;
a plurality of bottom electrodes on the semiconductor substrate at the cell area;
a dielectric layer conformally covering the bottom electrodes;
an upper electrode on the dielectric layer including,
a metal-containing layer conformally covering the dielectric layer, and
a silicon germanium layer on the metal-containing layer, the silicon germanium layer filling a space between the bottom electrodes, an entirety of a top surface of the silicon germanium layer being above top surfaces of the bottom electrodes, a side surface of the silicon germanium layer adjoining side surfaces of the bottom electrodes at a boundary between the cell area and the peripheral area; and
a first interlayer dielectric layer horizontally adjoining the side surface of the silicon germanium layer, the first interlayer dielectric layer covering the peripheral area, a top surface of the first interlayer dielectric layer being coplanar with the top surface of the silicon germanium layer.

20. The device of claim 19, wherein
a surface roughness of the top surface of the silicon germanium layer is about 10 nm Root Mean Square (RMS) or less, and
a surface roughness of the side surface of the silicon germanium layer is between about 10 nm RMS and about 1000 nm.

21. The device of claim 19, further comprising:
a second interlayer dielectric layer covering both the silicon germanium layer and the first interlayer dielectric layer, and
a plurality of upper electrode contact plugs penetrating the second interlayer dielectric layer and contacting the silicon germanium layer,
wherein the upper electrode contact plugs have depths each of which is measured from a top surface of the second interlayer dielectric layer to a bottom surface of a corresponding one of the upper electrode contact plugs, and a deviation of the depths ranges from about 0 nm to about 10 nm.

22. The device of claim 21, wherein each of the upper electrode contact plugs has a width greater than that of each of the bottom electrodes and vertically overlaps at least two bottom electrodes.
